(19) United States
(12) Patent Application Publication
(10) Pub. No.: US 2004/0106062 A1
(43) Pub. Date: Jun. 3, 2004

(54) Photoacid generators in photoresist compositions for microlithography

(76) Inventors: Viacheslav Alexandrovich Petrov, Hockessin, DE (US); Frank L Schadt III, Wilmington, DE (US)

Correspondence Address: E I du Pont de Nemours and Company, Legal-Patents, Wilmington, DE, 19898, US

(21) Appl. No.: 10/398,873

(22) PCT Filed: Oct. 31, 2001
(86) PCT No.: PCT/US01/48006

(51) Int. Cl. G03F 7/038; G03F 7/26

(52) U.S. Cl. 430/270.1; 430/325

(57) ABSTRACT

A photoresist composition having a polymeric binder; and a photoactive component selected from the group consisting of (1) hydroxamic acid sulfonoxy esters containing a perfluoroalkyl group containing at least five carbon atoms; (2) S-perfluoroalkyldibenzothiophenium salts, and (3) S-perfluoroalkyldiarylsulfonium salts. These photoactive components are compatible with the polymeric binders that are useful for imaging with exposure to light at the relatively shorter wavelengths, such as 157 nm.

### BACKGROUND OF THE INVENTION

1. Field of the Invention

The present invention pertains to a photoresist composition, in particular, for the production of semiconductor devices. The present invention also pertains to photoacid generators which are useful in photoresists particularly for imaging with exposure to light at relatively short wavelengths, e.g., 157 nm.

2. Description of Related Art

Polymer products are used as components of imaging and photosensitive systems and particularly in photoimaging systems such as those described in Introduction to Microlithography, Second Edition by L. F. Thompson, C. G. Willson, and M. J. Bowden, American Chemical Society, Washington, D.C., 1994. In such systems, ultraviolet (UV) light or other electromagnetic radiation impinges on a material containing a photoactive component to induce a physical or chemical change in that material. A useful or latent image is thereby produced which can be processed into a useful image for semiconductor device fabrication.

Although the polymer product itself may be photoactive, generally a photosensitive composition contains one or more photoactive components in addition to the polymer product. Upon exposure to electromagnetic radiation (e.g., UV light), the photoactive component acts to change the Theological state, solubility, surface characteristics, refractive index, color, electromagnetic characteristics or other such physical or chemical characteristics of the photosensitive composition as described in the Thompson et al. publication.

For imaging very fine features at the submicron level in semiconductor devices, electromagnetic radiation in the far or extreme ultraviolet (UV) is needed. Positive working photoresists generally are utilized for semiconductor manufacture. Lithography in the UV at 365 nm (I-line) using novolak polymers and diazonaphthoquinones as dissolution inhibitors is a currently established chip technology having a resolution limit of about 0.35-0.30 micron. Lithography in the far UV at 248 nm using p-hydroxystyrene polymers is known and has a resolution limit of 0.35-0.18 nm. There is strong impetus for future photolithography at even shorter wavelengths, due to a decreasing lower resolution limit with decreasing wavelength (i.e., a resolution limit of 0.18-0.12 micron for 193 nm imaging and a resolution limit of about 0.07 micron for 157 nm imaging). Photolithography using 193 nm exposure wavelength (obtained from an argon fluorine (ArF) excimer laser) is a leading candidate for future microelectronics fabrication using 0.18 and 0.13 μm design rules. Photolithography using 157 nm exposure wavelength (currently obtained from a fluorine excimer laser) is a leading candidate for future microlithography (beyond 193 nm) provided suitable materials can be found having sufficient transparency and other required properties at this very short wavelength.

A photoactive component (PAC) is usually utilized in the photoresist composition. It typically is a compound that produces either acid or base upon exposure to actinic radiation. If an acid is produced upon exposure to actinic radiation, the PAC is termed a photoacid generator (PAG). If a base is produced upon exposure to actinic radiation, the PAC is termed a photobase generator (PBG).

Some know photoacid generators include, but are not limited to, compounds represented by the structures below:

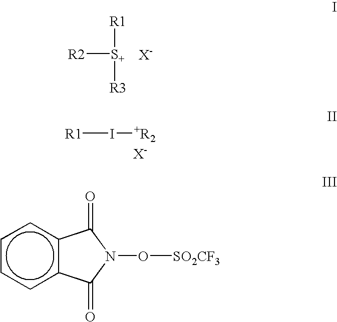

In structures I-II, R₁-R₃ are independently substituted or unsubstituted aryl or substituted or unsubstituted C₁-C₂₀ alkylaryl (aralkyl). Representative aryl groups include, but are not limited to, phenyl and naphthyl. Suitable substituents include, but are not limited to, hydroxyl (—OH) and C₁-C₂₀ alkyloxy (e.g., C₁₀H₂₁O). The anion X- in structures I-II can be, but is not limited to, SbF₆— (hexafluoroantimonate), CF₃SO₃— (trifluoromethylsulfonate=triflate), and C₄F₉SO₃— (perfluorobutylsulfonate).

A need still exists for photoacid generators that are not only transparent at short wavelengths but compatible with the polymeric binders that are useful at the shorter wavelengths.

### SUMMARY OF THE INVENTION

In a first aspect the invention provides a photoresist composition comprising: (a) a polymeric binder; and (b) a photoactive component selected from the group consisting of (1) a hydroxamic acid sulfonoxy ester containing an R_{f′} group, wherein R_{f′} is CₘF₂ₘ₊₁, m=is an integer of 5 to about 10; (2) an S-perfluoroalkyldibenzothiophenium salt wherein the alkyl group ranges from 1 to about 10 carbon atoms and (3) an S-perfluoroalkyldiarylsulfonium salt wherein the alkyl group ranges from 1 to about 10 carbon atoms.

More specifically, the invention is directed to a photoresist composition comprising: (a) a polymeric binder; and (b) a photoactive component selected from the group consisting of: (a) a hydroxamic acid

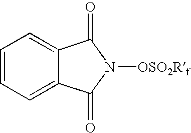

wherein R_{f′}=CₘF₂ₘ₊₁,

m is an integer of 5 to about 10,

(b) S-perfluoroalkyldibenzothiophenium salts represented by the structure:

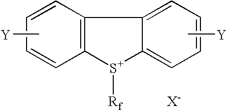

and (c) S-perfluoroalkyldiarylsulfonium salts represented by the structure:

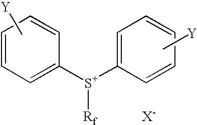

wherein,

X═OSO₂R_{f},

Y═R, NO₂, CN, halogen atom, —C(O)OR, —SO₂O—, or R_{f}; wherein R═CₚH₂ₚ₊₁, with p being an integer of 1 to about 10, and R_{f}=CₙF₂ₙ₊₁, with n being an integer of 1 to about 10.

In another aspect, the invention relates to a process for forming a relief image on a substrate having a photoresist layer comprising, in order: (a) imagewise exposing the photoresist layer to form imaged and non-imaged areas, wherein the photoresist layer is prepared from a photoresist composition comprising (b) a polymeric binder; and (c) a photoactive component selected from the group consisting of (a) the hydroxamic acid sulfonoxy ester containing the R_{f}′ group; (b) the S-perfluoroalkyldibenzothiophenium salt and (c) the S-perfluoroalkyldiarylsulfonium salt; and (d) developing the imagewise exposed photoresist layer to form the relief image on the substrate.

In one embodiment, the polymeric binder has an absorption coefficient of less than about 4.0 μm⁻¹ at a wavelength of 157 nm, typically, less than about 3.5 μm⁻¹ at a wavelength of 157 nm and even more typically, less than about 3.0 μm⁻¹ at a wavelength of 157 nm.

### DETAILED DESCRIPTION OF THE INVENTION

The photoresist compositions of the invention comprise a polymeric binder and a photoactive component.

Polymeric Binders:

The binders useful for this invention comprise any polymer which has the transparency properties suitable for use in microlithography. It is contemplated that binders suitable for the present invention may include those polymers which are typically incorporated into chemically amplified 248 (deep UV) and 193 nm photoresists for imaging at longer wavelengths. A typical 248 nm photoresist binder is based on polymers of para-hydroxystyrene. Other examples of suitable 248 nm photoresist binders can be found in the reference Introduction to Microlithography, Second Edition by L. F. Thompson, C. G. Willson, and M. J. Bowden, American Chemical Society, Washington, D.C., 1994, chapter 3. Binders useful for 193 nm photoresists include cycloolefin-maleic anhydride alternating copolymers [such as those disclosed in F. M. Houlihan et al., Macromolecules, 30, pages 6517-6534 (1997); T. Wallow et al., Proc. SPIE, 2724, 355; and F. M. Houlihan et al., Journal of Photopolymer Science and Technology, 10, 511(1997)], polymers of functionalized norbornene-type monomers prepared by metal-catalyzed vinyl addition polymerization or ring-opening metathesis polymerization [such as those disclosed in U. Okoroanyanwu et al. J. Mol. Cat A: Chemical 133, 93 (1998), and PCT WO 97/33198], and acrylate copolymers [such as those described in U.S. Pat. No. 5,372,912]. Photoresist binders that are suitable for use with this invention also include those which are transparent at wavelengths below 248 and 193 nm such as those polymers containing fluoroalcohol functional groups [such as those disclosed in K. J. Pryzbilla et al. Proc. SPIE 1672, 9 (1992), and H. Ito et al. Polymn. Mater Sci. Eng. 77, 449 (1997)].

Typical examples of polymers which are also useful are those which have been developed for use in chemically amplified photoresists which are imaged at an irradiation wavelength of 157 nm. Examples of such polymers are fluoropolymers and fluoropolymers containing fluoroalcohol functional groups. Suitable examples have been disclosed in WO 00/17712 and WO 00/25178.

The quantity of polymeric binder in the photoresist composition may be in the amount of about 50 to about 99.5 weight % based on the weight of the total photoresist composition (solids).

Photoactive Component (PAC)

The photoresist composition contains a combination of binder and photoactive component.

The photoactive component may be (1) a hydroxamic acid sulfonoxy ester represented by the structure:

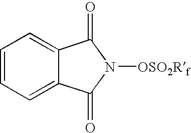

wherein R_{f′}=CₘF₂ₘ₊₁ and m is an integer of 5 to about 10, more typically m ranges from 5 to 8.

Some examples of the R_{f′} group include perfluoropentyl, perfluorohexyl, perfluoroheptyl, and perfluorooctyl.

Some suitable hydroxamic acid sulfonoxy esters represented by the above structure include N-perfluoropentylsulfonyloxy-phthaleimid, N-perfluorohexyl-sulfonyloxyphthaleimid, N-perfluoroheptyl-sulfonyloxyphthaleimid, and N-perfluorooctylsulfonyloxyphthaleimid. These compounds may be prepared by reaction of the thallous salt of N-hydroxyphtalimide and the anhydride of triflic acid in methylene chloride as a solvent by known methods, for example as reported in J. Org. Chem., 38<1973>22, 3908-3911 by Chapman, T. M.; Freedman, E. A.

Additionally, the photoactive component may be an S-perfluoroalkyldibenzothiophenium salt represented by the structure:

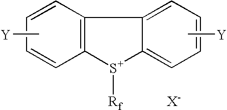

wherein,

X═OSO₂R_{f},

Y=halogen atom, such as F, Cl, Br, I; R group; NO₂; CN; —C(O)OR, SO₂O— or R_{f}; wherein R is CₚH₂ₚ₊₁, wherein p is an integer ranging from 1 to about 10, typically from 1 to about 5 such as CH₃, C₂H₅, C₃H₇, etc. and R_{f}=CₙF₂ₙ₊₁, with n being an integer of 1 to about 10

Some suitable compounds represented by the above structure include S-(trifluoromethyl)dibenzothiophenium triflate (trifluoromethane sulfonate), S-(pentalfluoroethyl)dibenzo-thiophenium pentaflate (X═C₂F₅SO₂₀—), S-(heptafluoropropyl)dibenzo-thiophenium nonaflate (X═C₄F₉SO₂O—), S-(n-perfluorooctyl)dibenzo-thiophenium triflate or S-(nonafluorobutyl)dibenzo-thiophenium perfluoro-pentylsulfonate (X═C₅F₁₁SO₂O—), etc. They may carry different substituents in the phenyl rings, such as halogen atom (such as fluorine, chlorine, bromine, iodine), alkyl, designated by the group R which is CₚH₂ₚ₊₁, wherein p is an integer ranging from 1 to about 10, typically from 1 to about 5 such as CH₃, C₂H₅, C₃H₇; —CN, —C(O)OR, nitro, perfluoroalkyl-. Some compounds are available from chemical suppliers such as, for example, Synquest Co. or Daikin Chemical Sales, Ltd. These materials can be prepared in one-step process by reaction of corresponding 2-[(S-perfluoroalkyl)thio]biphenyl with diluted fluorine gas in the presence of triflic acid or boron trifluoride etherate in inert solvent at low temperature (temperature range −50 to 0° C.), or in two step process involving conversion of 2-[(S-perfluoroalkyl)thio]biphenyl into corresponding sulfoxide by oxidation with m-chloroperoxybenzoic acid, followed by intramolecular cyclization of sulfoxide into final product in the presence of triflic anhydride. Both procedures were reported in Journal American Chemical Society 1993, v.115 p. 2156-2164, by T. Umemoto and S. Ishihara, Tetrahedron Letters 1990, v.31, p.3579-3582 by T. Umemoto and S. Ishihara. Methods of preparation of these materials has been also reviewed in Chemical Reviews 1996, v.96, pp. 1757-1777. Further modification of S-(perfluoroalkyl)dibenzothiophenium salts can be achieved for example by introduction of nitro- or sulfonato-groups into the 3 and 7 position of an aromatic system by reaction of S-(perfluoroalkyl)dibenzothiophenium salts with fumic sulfuric acid at 40° C., followed by nitration of product by a mixture of fumic sulfuric and concentrated nitric acids at ambient temperature. This procedure was reported in Journal of Fluorine Chemistry, 1995, v.74, p.77 by T. Umemoto, S. Ishihara and K. Adachi.

Additionally, the photoactive component may be S-perfluoroalkyldiarylsulfonium salts represented by the structure:

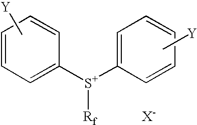

wherein,

X═OSO₂R_{f},

Y=halogen such as F, Cl, Br, I; R; NO₂; CN; —C(O)OR —SO₂O—; or R_{f}; wherein R═CₚH₂ₚ₊₁, with p being an integer ranging from 1 to about 10, typically 1 to about 5 such as CH₃, C₂H₅, C₃H₇, etc., and R_{f}=CₙF₂ₙ₊₁, with n being an integer of 1 to about 10.

Some suitable compounds represented by the above structure include, but are not limited to, S-trifluoromethyldiphenylsulfonium triflate S-(pentalfuoroethyl)diphenylsulfonium pentafluoroethylsulfonate, S-(heptafuoroprpopyl)diphenylsulfonium nonafluorobutylsulfonate, S-(nonafluorobutyl)diphenylsulfonium perfluorooctylsulfonate etc. They may carry different substituents in the phenyl rings such as halogen atom (such as fluorine, chlorine, bromine, iodine), alkyl designated by the group R which is CₚH₂ₚ₊₁, wherein p is an integer ranging from 1 to about 10, typically from 1 to about 5 such as CH₃, C₂H₅, C₃H₇, etc., —CN, —C(O)OR, nitro, perfluoroalkyl-. This type of materials can be prepared by intermolecular reaction of aryl trifluoromethyl sulfoxide with a corresponding arene. For example, the preparation of (S-trifluoromethyl)diphenylsulfonium triflate may be by reaction of phenyltrifluoromethylsulfoxide and benzene in triflic anhydride at ambient temperature. This procedure was reported in Journal American Chemical Society 1993, v.115 p. 2156-2164 by T. Umemoto and S. Ishihara.

The photoactive compound may be present in the amount of about 0.5 to about 10% by weight typically about 1 to about 5% by weight, based on the total dry weight of photoresist composition.

Dissolution Inhibitor

Various dissolution inhibitors can be utilized in this invention. Ideally, dissolution inhibitors (DIs) for the far and extreme UV photoresists (e.g., 193 nm photoresists) are selected to satisfy multiple needs including dissolution inhibition, plasma etch resistance, and adhesion behavior of photoresist compositions comprising a given DI additive. Typically, a dissolution inhibitor is included in a photoresist composition to assist in the development process. A good dissolution inhibitor will inhibit the unexposed areas of the photoresist layer from dissolving during the development step in a positive working system. A useful dissolution inhibitor may also function as a plasticizer which function provides a less brittle photoresist layer that will resist cracking. These features are intended to improve contrast, plasma etch resistance, and adhesion behavior of photoresist compositions.

Some dissolution inhibiting compounds also serve as plasticizers in photoresist compositions.

A variety of bile-salt esters (i.e., cholate esters) are particularly useful as dissolution inhibitors in the compositions of this invention. Bile-salt esters are known to be effective dissolution inhibitors for deep UV photoresists, beginning with work by Reichmanis et al. in 1983. (E. Reichmanis et al., “The Effect of Substituents on the Photosensitivity of 2-Nitrobenzyl Ester Deep UV Resists”, J. Electrochem. Soc. 1983, 130, 1433-1437.) Bile-salt esters are particularly attractive choices as dissolution inhibitors for several reasons, including their availability from natural sources, their possessing a high alicyclic carbon content, and particularly for their being transparent in the deep and vacuum UV region, (which essentially is also the far and extreme UV region), of the electromagnetic spectrum (e.g., typically they are highly transparent at 193 nm). Furthermore, the bile-salt esters are also attractive dissolution inhibitor choices since they may be designed to have widely ranging hydrophobic to hydrophilic compatibilities depending upon hydroxyl substitution and functionalization.

Representative bile-acids and bile-acid derivatives that are suitable as dissolution inhibitors for this invention include, but are not limited to, those illustrated below, which are as follows: cholic acid (IV), deoxycholic acid (V), lithocholic acid (VI), t-butyl deoxycholate (VII), t-butyl lithocholate (VIII), and t-butyl-3-α-acetyl lithocholate (IX). Bile-acid esters, including compounds VII-IX, are preferred dissolution inhibitors in this invention.

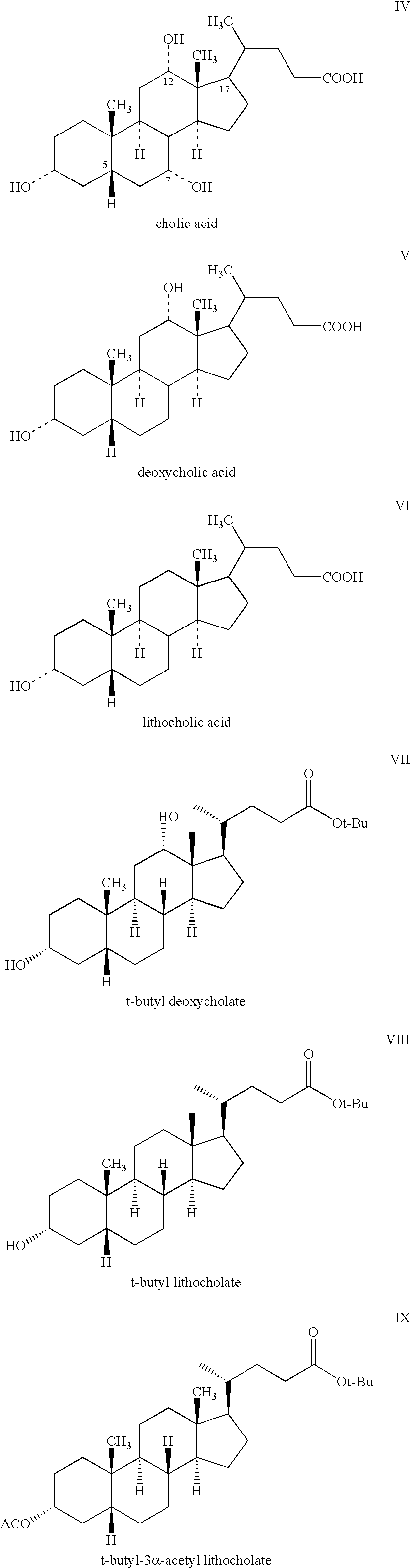

The quantity of dissolution inhibitor in the photoresist composition may range from about 0.5 to about 50 weight % based on the total weight of the solids in the photoresist composition.

Other Components

The compositions of this invention can contain optional additional components. Examples of additional components which can be added include, but are not limited to, resolution enhancers, adhesion promoters, residue reducers, coating aids, plasticizers, and T_{g} (glass transition temperature) modifiers. Crosslinking agents may also be present in negative-working photoresist compositions. Some typical crosslinking agents include bis-azides, such as, 4,4′-diazidodiphenyl sulfide and 3,3′-diazidodiphenyl sulfone. Typically, a negative working composition containing at least one crosslinking agent also contains suitable functionality (e.g., unsaturated C═C bonds) that can react with the reactive species (e.g., nitrenes) that are generated upon exposure to UV to produce crosslinked polymers that are not soluble, dispersed, or substantially swollen in developer solution.

Solvent

The photoresist composition can include an amount of solvent, typically an organic solvent such as cyclohexanone. The solvent is usually used in an amount sufficient to dissolve the binder and the photoactive component. A specific solvent found to be useful is cyclohexanone.

Process For Forming a Photoresist Image

The process for forming a photoresist image on a substrate comprises, in order:

(A) imagewise exposing a photoresist layer to form imaged and non-imaged areas, wherein the photoresist layer is prepared from a photoresist composition comprising:

(a) a polymeric binder; and

(b) a photoactive component selected from the group consisting of compounds (1), (2), and (3) as described above;

(B) developing the exposed photoresist layer having imaged and non-imaged areas to form the relief image on the substrate.

The photoresist layer is prepared by applying a photoresist composition onto a substrate and drying to remove the solvent. The photoresist layer is, typically, applied by spin coating onto a substrate, typically a silicon wafer having a primer applied thereon. The so formed photoresist layer is sensitive in the ultraviolet region of the electromagnetic spectrum and especially to those wavelengths ≦365 nm. Imagewise exposure of the photoresist compositions of this invention can be done at many different UV wavelengths including, but not limited to, 365 nm, 248 nm, 193 nm, 157 nm, and lower wavelengths. Imagewise exposure is preferably done with ultraviolet light of 248 nm, 193 nm, 157 nm, or lower wavelengths, preferably it is done with ultraviolet light of 193 nm, 157 nm, or lower wavelengths, and most preferably, it is done with ultraviolet light of 157 nm or lower wavelengths. Imagewise exposure can either be done digitally with a laser or equivalent device or non-digitally with use of a photomask. Digital imaging with a laser is preferred. Suitable laser devices for digital imaging of the compositions of this invention include, but are not limited to, an argon-fluorine excimer laser with UV output at 193 nm, a krypton-fluorine excimer laser with UV output at 248 nm, and a fluorine (F₂) laser with output at 157 nm. Since, as discussed supra, use of UV light of lower wavelength for imagewise exposure corresponds to higher resolution (lower resolution limit), the use of a lower wavelength (e.g., 193 nm or 157 m or lower) is generally preferred over use of a higher wavelength (e.g., 248 nm or higher). After exposure, the wafer is usually baked to increase or decrease the ability of exposed areas of the photoresist to be removed in developer. The photoresist compositions of this invention must contain sufficient functionality for development following imagewise exposure to UV light. Preferably, the functionality is an acid or protected acid such that aqueous development is possible using a basic developer such as sodium hydroxide solution, potassium hydroxide solution, or ammonium hydroxide solution, such as tetramethylammonium hydroxide.

When an aqueous processable photoresist is coated or otherwise applied to a substrate and imagewise exposed to UV light, development of the photoresist composition may require that the binder material should contain sufficient acid groups (e.g., fluoroalcohol groups) and/or protected acid groups that are at least partially deprotected upon exposure to render the photoresist (or other photoimageable coating composition) processable in aqueous alkaline developer. In case of a positive-working photoresist layer, the photoresist layer will be removed during development in portions which are exposed to UV radiation but will be substantially unaffected in unexposed portions during development by aqueous alkaline liquids such as wholly aqueous solutions containing 0.262 N tetramethylammonium hydroxide (with development at 25° C. usually for less than or equal to 120 seconds). In case of a negative-working photoresist layer, the photoresist layer will be removed during development in portions which are unexposed to UV radiation but will be substantially unaffected in exposed portions during development using either a critical fluid or an organic solvent.

A critical fluid, as used herein, is one or more substances heated to a temperature near or above its critical temperature and compressed to a pressure near or above its critical pressure. Critical fluids in this invention are at least at a temperature that is higher than 15° C. below the critical temperature of the fluid and are at least at a pressure higher than 5 atmospheres below the critical pressure of the fluid. Carbon dioxide may be used for the critical fluid in the present invention. Various organic solvents can also be used as developer in this invention. These include, but are not limited to, halogenated solvents and non-halogenated solvents. Halogenated solvents are typical and fluorinated solvents are more typical.

Substrate

The substrate employed in this invention can be any material used in semiconductor manufacture, for example, a wafer usually made from silicon, silicon oxide, silicon nitride and the like. Usually, a primer is applied to the silicon wafer. A typical primer composition is hexamethyldisilazane.

### EXAMPLES

### Example 1

In this example a copolymer of a norbornene fluoroalcohol monomer (NB-F-OH) and a methoxy methyl ether-protected norbornene fluoroalcohol monomer (NB-F-OMOM) was used. The copolymer was made according to a procedure similar to that described in Example 27 WO 00/67072. The NB-F-OH monomer was made-in accordance with Example 13 of WO 00/67072 and the methoxymethylether monomer (NB-F-OMOM) was made in accordance with Example 14 of WO 00/67072.

The copolymer was made by copolymerization of an unprotected norbornene fluoroalcohol (NB-F-OH) with a methoxy methyl ether-protected norbornene fluoroalcohol (NB-F-OMOM)(molar feed ratio=80/20), to give a copolymer that was insoluble in aqueous base developer.

Under nitrogen, 1.01 g (2.58 mmol) of the allyl palladium complex [(ρ³-MeCHCHCH₂)PdCl]₂ and 1.0 g (5.14 mmol) silver tetrafluoroborate were suspended in chlorobenzene (75 mL). The resulting mixture was stirred at room for 45 minutes. It was then filtered to remove precipitated AgCl. The resulting solution was added to a mixture of 17.25 g (51.6 mmol) NB-F-OMOM, 59.9 g (206.4 mmol) NB-F-OH, and chlorobenzene (˜500 mL). The resulting reaction mixture was stirred for 1 day at room temperature. The crude product polymer was isolated by filtration and washed with hexane. This material was taken up in THF to give a ˜13 wt. % solution. 20 g of Polyvinyl pyridine (25% crosslinked) was added to the 10 wt. % solution in THF and the mixture was hydrogenated at 75° C. and 1000 lb pressure for 18 hours. Resultant product was filtered through a 0.2 μm nylon filter; the THF filtrate was then concentrated to dryness, affording 52.4 g of addition copolymer. GPC: Mₙ=16138; M_{w}=31594; M_{w}/Mₙ=1.96. ¹⁹F NMR (δ, Acetone-d6)-75.09 [(CF₃)₂COCH₂OMe], −76.8 [(CF₃)₂COH]. ¹H (acetone-d6) NMR spectra was consistent with a random saturated vinyl addition copolymer. From integration of the ¹⁹F NMR absorptions the polymer was determined to contain repeat units derived as follows: 86 mole % derived from NB-F-OH and 14 mole % derived from NB-F-OMOM.

The resulting copolymer was formulated into a photoresist composition by preparing a solution of the following components which were combined and magnetically stirred overnight.

| Component | Wt. (gm) |
|---|---|
| NB—F—OH/NB—F—OMOM copolymer | 0.613 |
| (molar ratio: 80/20 feed, analyzed 86/14 by | |
| NMR) | |
| Cyclohexanone | 5.044 |
| t-Butyl Lithocholate | 0.090 |
| 6.82% (wt) solution of S-(trifluoromethyl)- | 0.253 |
| dibenzothiophenium trifluoromethanesulfonate, | |
| dissolved in cyclohexanone, which had been | |
| filtered through a 0.45μ PTFE syringe filter | |
| purchased from Aldrich. | |

Spin coating was done using a Brewer Science, Inc. Model-100CB combination spin coater/hotplate on a 4 inch (10.16 cm) diameter Type “P”, <100> orientation, silicon wafer. Development was performed on a Litho Tech Japan Co. Resist Development Analyzer (Model-790).

The wafer was prepared by depositing about 0.75 ml of hexamethyldisilazane (HMDS) primer and spinning at 3000 rpm for 60 seconds. Then about 0.5 ml of the above solution, after filtering through a 0.45 μm glass syringe filter, was deposited and spun at 3000 rpm for 60 seconds and baked at 120° C. for 60 seconds.

248 nm imaging was accomplished by exposing the coated wafer to light obtained by passing broadband UV light from an ORIEL Model-82421 Solar Simulator (1000 watt) through a 248 nm interference filter which passes about 30% of the energy at 248 nm. Exposure time was 30 seconds, providing an unattenuated dose of 20.5 mJ/cm². By using a mask with 18 positions of varying neutral optical density, a wide variety of exposure doses were generated. After exposure the exposed wafer was baked at 100° C. for 60 seconds.

The wafer was developed in aqueous tetramethylammonium hydroxide (TMAH) solution (OHKA NMD-3, 2.38% TMAH solution) for 60 seconds. This test generated a positive image with a clearing dose of about 3.5 mJ/cm².

What is claimed is:

1. A photoresist composition comprising:
(a) a polymeric binder; and
(b) a photoactive component selected from the group consisting of
(1) a hydroxamic acid sulfonoxy ester containing an R_{f} group, wherein R_{f′} is CₘF₂ₘ₊₁, wherein m is an integer of 5 to about 10;
(2) an S-perfluoroalkyldibenzothiophenium salt wherein the alkyl group ranges from 1 to 10 carbon atoms and
(3) an S-perfluoroalkyldiarylsulfonium salt wherein the alkyl group ranges from 1 to 10 carbon atoms.

2. The photoresist composition of claim 1 in which the hydroxamic acid sulfonoxy ester is represented by the structure: 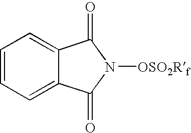
wherein R_{f′}=CₘF₂ₘ₊₁, and
m is an integer ranging from 5 to about 10.

3. The photoresist composition of claim 1 in which the (2) S-perfluoroalkyldibenzothiophenium salt is represented by the structure: 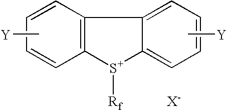
wherein,
X═OSO₂R_{f}, and
Y═R, NO₂, CN, halogen atom, —C(O)OR, —SO₂O—, or R_{f} group; wherein R=CₚH₂ₚ₊₁, with p being an integer of 1 to about 10, and R_{f}=CₙF₂ₙ₊₁, with n being an integer of 1 to about 10.

4. The photoresist composition of claim 1 in which the (3) S-perfluoroalkyldiarylsulfonium salt is represented by the structure: 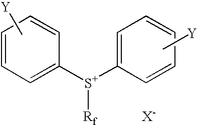
wherein,
X═OSO₂R_{f}, and
Y═R, NO₂, CN, halogen atom, —C(O)OR, —SO₂O—, or R_{f} group; wherein R=CₚH₂ₚ₊₁, with p being an integer of 1 to about 10, and R_{f}=CₙF₂ₙ₊₁, with n being an integer of 1 to about 10.

5. The photoresist composition of claim 1 wherein the polymeric binder has an absorption coefficient of less than about 4.0 μm⁻¹ at a wavelength of 157 nm.

6. The photoresist composition of claim 1 wherein the hydroxamic acid sulfonoxy ester is selected from the group consisting of N-perfluoropentylsulfonyloxyphthaleimid, N-perfluorohexylsulfonyloxyphthaleimid, N-perfluoroheptylsulfonyloxyphthaleimid, and N-perfluorooctylsulfonyloxyphthaleimid.

7. The photoresist composition of claim 1 wherein the S-perfluoroalkyldibenzothiophenium salt is selected from the group consisting of S-(trifluoromethyl)dibenzothiophenium triflate, S-(pentalfuoroethyl)dibenzo-thiophenium pentaflate,
S-(heptafluoropropyl)dibenzothiophenium nonaflate, S-(n-perfluorooctyl) dibenzothiophenium triflate and S-(nonafluorobutyl)dibenzothiophenium perfluoropentylsulfonate.

8. The photoresist composition of claim 3 wherein at least one phenyl ring of the S-perfluoroalkyldibenzothiophenium salt is substituted with halogen atom, alkyl group designated by R, —CN, —C(O)OR, nitro or perfluoroalkyl-, wherein R=CₚH₂ₚ₊₁, with p being an integer of 1 to about 10.

9. The photoresist composition of claim 1 wherein the S-perfluoroalkyldiarylsulfonium salt is selected from the group consisting of S-trifluoromethyldiphenylsulfonium triflate, S-(pentalfuoroethyl)diphenylsulfonium pentafluoroethylsulfonate, S-(heptafuoroprpopyl)diphenylsulfonium nonafluorobutylsulfonate, S-(nonafluorobutyl)diphenylsulfonium and perfluorooctylsulfonate.

10. The photoresist composition of claim 4 wherein at least one phenyl ring of the S-perfluoroalkyldiarylsulfonium salt is substituted with halogen atom, alkyl group designated by R, —CN, —C(O)OR, nitro or perfluoroalkyl-, wherein R=CₚH₂ₚ₊₁, with p being an integer of 1 to about 10.

11. The photoresist composition of claim 1 wherein the photoactive component is present in the amount of about 0.5 to about 10% by weight based on the weight of the total photoresist composition.

12. The photoresist composition of claim 1 wherein the polymeric binder is a fluoropolymer.

13. The photoresist composition of claim 10 wherein the fluoropolymer is NB-F-OH-/NB-F-OMOM.

14. The photoresist composition of claim 1 further comprising a dissolution inhibitor.

15. The photoresist composition of claim 14 in which the dissolution inhibitor is tert butyl lithocholate.

16. The photoresist composition of claim 1 further comprising a solvent.

17. The photoresist composition of claim 16 in which the solvent is cyclohexanone.

18. A process for forming a relief image on a substrate having a photoresist layer comprising, in order:
(A) imagewise exposing the photoresist layer to form imaged and non-imaged areas, wherein the photoresist layer is prepared from a photoresist composition comprising:
(a) a polymeric binder; and
(b) a photoactive component selected from the group consisting of
(1) a hydroxamic acid sulfonoxy ester containing an R_{f′} group, wherein R_{f′} is CₘF₂ₘ₊₁, m=is an integer of 5 to about 10;
(2) an S-perfluoroalkyldibenzothiophenium salt wherein the alkyl group ranges from 1 to 10 carbon atoms; and
(3) an S-perfluoroalkyldiarylsulfonium salt wherein the alkyl group ranges from 1 to 10 carbon atoms. and
(B) developing the imagewise exposed photoresist layer to form the relief image on the substrate.

19. The process of claim 18 wherein the polymeric binder has an absorption coefficient of less than about 4.0 μm⁻¹ at a wavelength of 157 nm.

20. The process of claim 18 in which the (1) hydroxamic acid sulfonoxy ester is represented by the structure: 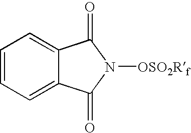
wherein R_{f′}=CₘF₂ₘ₊₁, and
m is an integer ranging from 5 to about 10.

21. The process of claim 18 in which the (2) S-perfluoroalkyldibenzothiophenium salt is represented by the structure: 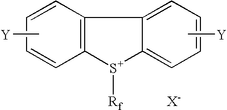
wherein,
X═OSO₂R_{f}, and
Y═R, NO₂, CN, halogen atom, —C(O)OR, —SO₂O—, or R_{f}; wherein R=CₚH₂ₚ₊₁, with p being an integer of 1 to about 10; and R_{f}=CₙF₂ₙ₊₁, with n being an integer of 1 to about 10.

22. The process of claim 18 in which the (3) S-perfluoroalkyldiarylsulfonium salt is represented by the structure: 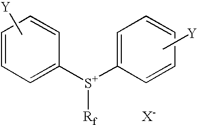
wherein
X═OSO₂R_{f}, and
Y═R, NO₂, CN, halogen atom, —C(O)OR, —SO₂O—, or R_{f}; wherein R=CₚH₂ₚ₊₁, with p being an integer of 1 to about 10; and R_{f}=CₙF₂ₙ₊₁, with n being an integer of 1 to about 10.

23. The process of claim 18 wherein the hydroxamic acid sulfonoxy ester is selected from the group consisting of N-perfluoropentylsulfonyloxyphthaleimid, N-perfluorohexylsulfonyloxyphthaleimid, N-perfluoroheptylsulfonyloxyphthaleimid, and N-perfluorooctylsulfonyloxyphthaleimid.

24. The process of claim 18 wherein the S-perfluoroalkyldibenzothio-phenium salt is selected from the group consisting of S-(trifluoromethyl)-dibenzothiophenium triflate, S-(pentalfuoroethyl)dibenzo-thiophenium pentaflate, S-(heptafluoropropyl)dibenzothiophenium nonaflate and S-(nonafluorobutyl)dibenzothiophenium perfluoropentylsulfonate.

25. The process of claim 21 wherein at least one phenyl ring of the S-perfluoroalkyldibenzothio-phenium salt is substituted with halogen atom, alkyl group designated by R, —CN, —C(O)OR, nitro or perfluoroalkyl-, wherein R=CₚH₂ₚ₊₁, with p being an integer of 1 to 10; —CN, —C(O)OR, nitro or perfluoroalkyl-, wherein R=CₙH₂ₙ₊₁, with n being an integer of 1 to about 10.

26. The process of claim 18 wherein the S-perfluoroalkyldibenzothio-phenium salt is selected from the group consisting of S-trifluoromethyldiphenylsulfonium triflate, S-(pentalfuoroethyl)diphenylsulfonium pentafluoroethylsulfonate, S-(heptafuoroprpopyl)diphenylsulfonium nonafluorobutylsulfonate, S-(nonafluorobutyl)diphenylsulfonium and perfluorooctylsulfonate.

27. The process of claim 22 wherein at least one phenyl ring of the S-perfluoroalkyldibenzothio-phenium salt is substituted with halogen atom, alkyl group designated by R, —CN, —C(O)OR, nitro or perfluoroalkyl-, wherein R=CₚH₂ₚ₊₁, with p being an integer of 1 to 10; —CN, —C(O)OR, nitro or perfluoroalkyl-, wherein R=CₙH₂ₙ₊₁, with n being an integer of 1 to about 10.

28. The photoresist composition of claim 18 wherein photoactive component is present in the amount of about 0.5 to about 10% by weight, based on the total weight of photoresist composition.
